(19) United States
(12) Patent Application Publication
(10) Pub. No.: US 2026/0148662 A1
(43) Pub. Date: May 28, 2026

(54) SIMULATION SYSTEM

(71) Applicant: TOYOTA JIDOSHA KABUSHIKI KAISHA, Toyota-shi (JP)

(72) Inventor: Eisuke AOKI, Toyota-shi (JP)

(73) Assignee: TOYOTA JIDOSHA KABUSHIKI KAISHA, Toyota-shi (JP)

(21) Appl. No.: 19/272,254

(22) Filed: Jul. 17, 2025

(30) Foreign Application Priority Data
Nov. 26, 2024 (JP) 2024-205705

(51) Int. Cl. G09B 23/30; G06F 30/20

(52) U.S. Cl. CPC G09B 23/30; G06F 30/20

(57) ABSTRACT

A simulation device of a musculoskeletal model includes a plurality of muscle sites disposed along a skeleton, including a measurement result acquisition unit and an adjustment unit. The measurement result acquisition unit is configured to acquire a first measurement result that is a measurement result of muscle strength measurement using a plurality of muscle sites belonging to an SFL of a subject, and a second measurement result that is a measurement result of a muscle strength measurement using a plurality of muscle sites belonging to an SBL of the subject. The adjustment unit is configured to execute an adjustment process of adjusting muscle strength of at least one of the muscle sites belonging to the SFL and the muscle sites belonging to the SBL in the musculoskeletal model based on a comparison result of the first measurement result and the second measurement result.

### CROSS-REFERENCE TO RELATED APPLICATION

This application claims priority to Japanese Patent Application No. 2024-205705 filed on Nov. 26, 2024. The disclosure of the above-identified application, including the specification, drawings, and claims, is incorporated by reference herein in its entirety.

### BACKGROUND

### 1. Technical Field

The present disclosure relates to a simulation system.

### 2. Description of Related Art

In a simulation system of a musculoskeletal model including a plurality of muscle sites disposed along a skeleton, a system such as AnyBody (registered trademark) developed and popularized by Aalborg University in Denmark is known. In such a simulation system, it is possible to perform a simulation while changing the value of a muscle mass of each muscle constituting the musculoskeletal model.

Japanese Patent No. 5920724 (JP 5920724 B) discloses a configuration in which a muscle strength is adjusted in a muscle group unit in which a plurality of muscles is grouped. More specifically, the example of simulating how the values of each of the six types of muscle groups included in the set of muscle groups (hip flexor muscle group, hip extensor muscle group, hip internal rotator muscle group, hip external rotator muscle group, hip adductor muscle group, and hip abductor muscle group) change by setting the clothing conditions (conditions 0 to 6) is disclosed.

### SUMMARY

In the simulation of the effect of the exercise on the muscle, there is a variation in muscle strength for each part of the body depending on individuals even under the same clothing condition. Therefore, unless such a variation is taken into consideration, it is not possible to accurately perform the simulation of the musculoskeletal system tailored to the individual. Even when machine learning is used, this problem is difficult to solve.

An object of the present disclosure is to provide a technique for efficiently improving the accuracy of a simulation of a musculoskeletal model based on a variation in muscle development among individuals.

A simulation system of a musculoskeletal model including a plurality of muscle sites disposed along a skeleton includes:
a measurement result acquisition section configured to acquire a first measurement result that is a measurement result of a muscle strength measurement using a plurality of muscle sites belonging to a first anatomy train of a subject, and a second measurement result that is a measurement result of a muscle strength measurement using a plurality of muscle sites belonging to a second anatomy train of the subject, the second anatomy train having an antagonistic muscle relationship with the first anatomy train; and
an adjustment section configured to execute an adjustment process of adjusting muscle site parameters of at least one of the muscle sites belonging to the first anatomy train and the muscle sites belonging to the second anatomy train in the musculoskeletal model, based on a comparison result of the first measurement result and the second measurement result.

The adjustment section may be configured to execute the adjustment process based on a ratio of the first measurement result to the second measurement result.

The adjustment section may be configured to execute the adjustment process such that a ratio of the muscle site parameters of the muscle sites belonging to the first anatomy train to the muscle site parameters of the muscle sites belonging to the second anatomy train in the musculoskeletal model approaches the ratio of the first measurement result to the second measurement result of the subject.

The first anatomy train may be a superficial front line (SFL), and the second anatomy train may be a superficial back line (SBL).

The first anatomy train may be a front functional line (FFL), and the second anatomy train may be a back functional line (BFL).

According to the present disclosure, it is possible to efficiently improve the accuracy of the simulation of the musculoskeletal model based on the variation in muscle development among individuals.

### BRIEF DESCRIPTION OF THE DRAWINGS

Features, advantages, and technical and industrial significance of exemplary embodiments of the disclosure will be described below with reference to the accompanying drawings, in which like signs denote like elements, and wherein:

FIG. 1 is a block diagram of a simulation device.

### DETAILED DESCRIPTION OF EMBODIMENTS

Hereinafter, the present disclosure will be described through embodiments of the disclosure, but the disclosure according to the claims is not limited to the following embodiments. Moreover, not all of the configurations described in the embodiments are indispensable as means for solving the problem. In order to clarify the description, the following description and drawings are omitted and simplified as appropriate. In drawings, the same elements are designated by the same reference numerals, and repeated descriptions thereof are omitted as necessary.

In the following embodiments, when needed, the embodiments will be described in a divided manner into a plurality of sections or embodiments, but unless otherwise specified, the embodiments are not unrelated to each other, and one embodiment is related to the other embodiment in a relationship of a modification example, an application example, a detailed description, a supplementary description, or the like of a part or all of the other embodiment. In addition, in the following embodiments, when the number of elements or the like (including the number, the value, the amount, the range, and the like) is referred to, the number is not limited to the specific number, and may be equal to or more than or less than the specific number, except when the number is specifically limited and when the number is limited in principle.

Further, in the following embodiment, the configuration elements (including the operation steps and the like) are not necessarily essential, except when they are particularly described or are considered to be essential in principle. Similarly, in the following embodiments, when the shape, the positional relationship, or the like of the constituent elements is referred to, the shape, the positional relationship, or the like is substantially approximated or similar to the shape, the positional relationship, or the like, unless otherwise specified or unless it is considered that the shape, the positional relationship, or the like is not clear in principle. The same applies to the above-described numbers (including the number, the value, the amount, and the range).

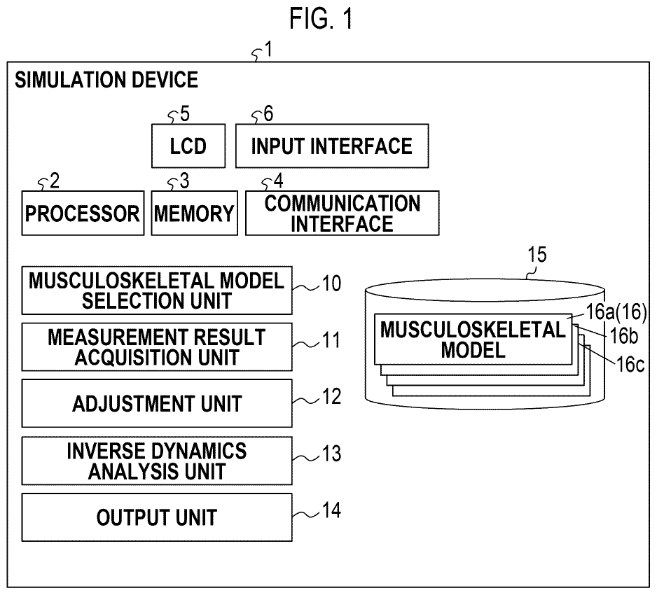

Hereinafter, a simulation device 1 according to an embodiment of the present disclosure will be described with reference to FIG. 1. FIG. 1 is a block diagram of the simulation device 1. The simulation device 1 is a specific example of a simulation system that estimates fatigue or energy consumption of the subject for each muscle site by using the musculoskeletal model for the inverse dynamics analysis. The musculoskeletal model includes a skeleton and a plurality of muscle sites disposed along the skeleton. In the simulation device 1, the muscle site parameters of a plurality of muscle sites are tuned to estimate the fatigue and energy consumption of the subject for each muscle site of the subject with higher accuracy. The simulation device 1 may be realized by a single device or may be realized by distributed processing by a plurality of devices.

As shown in FIG. 1, the simulation device 1 includes a processor 2, a memory 3, a communication interface 4, a liquid crystal display (LCD) 5, and an input interface 6.

The processor 2 can access the memory 3. The processor 2 is configured to be able to communicate with an external device via the communication interface 4. The processor 2 reads and executes a program stored in the memory 3. As a result, the processor 2 causes the hardware, such as the processor 2, to function as the musculoskeletal model selection unit 10, the measurement result acquisition unit 11, the adjustment unit 12, the inverse dynamics analysis unit 13, and the output unit 14. The memory 3 also stores a musculoskeletal model database 15.

The LCD 5 is a specific example of an output device. The input interface 6 is a specific example of an input device. The input interface 6 is typically configured by a touch panel superimposed on the LCD 5.

The musculoskeletal model database 15 includes a plurality of musculoskeletal models 16. Each musculoskeletal model 16 has an initial value (reference value) of the muscle site parameter for each of 600 or more muscle sites. Examples of the musculoskeletal models 16 include an AM50 model 16a, a GM model 16b, and a JAMA50 16c.

The AM50 model 16a is a musculoskeletal model called a “50th Percentile American Male”, and is a musculoskeletal model corresponding to 50th percentile (median) of American males. In short, it can be said that the AM50 model 16a represents the average height, weight, body type, and muscle mass of an American adult man.

The GM model 16b is a musculoskeletal model also called a global human body models consortium (GHBMC), and is a globally standardized musculoskeletal model. That is, the GM model 16b is based on data of various races and genders. In the present embodiment, the GM model 16b is a so-called musculoskeletal model corresponding to the 50th. However, the GM model 16b is not limited to this, and may be a so-called 5th or 95th corresponding to the musculoskeletal model.

The JAMA50 16c is a musculoskeletal model also referred to as “Japanese Anthropometric Model for the 50th Percentile Japanese Male”, and is a musculoskeletal model based on the 50th percentile of Japanese men. Therefore, the JAMA50 16c reflects the average body size and muscle mass of Japanese people.

In the present embodiment, the “muscle site parameter” is a parameter related to the muscle site, and typically means muscle mass or muscle strength. In other words, the muscle mass or muscle strength is a specific example of the muscle site parameter. It is generally considered that there is a proportional relationship between the muscle mass and the muscle strength. However, the muscle strength decreases with aging, but the muscle mass does not decrease so much. In the present embodiment, the muscle site parameter will be described as muscle strength.

The musculoskeletal model selection unit 10 acquires the musculoskeletal model 16 selected from the musculoskeletal models 16 stored in the musculoskeletal model database 15 via the input interface 6. Typically, the musculoskeletal model 16 closest to the musculoskeletal of the subject is selected.

The measurement result acquisition unit 11 acquires a first measurement result that is a measurement result of the muscle strength measurement using a plurality of muscle sites belonging to the first anatomy train of the test subject, and a second measurement result that is a measurement result of the muscle strength measurement using a plurality of muscle sites belonging to the second anatomy train of the test subject that is in an antagonistic muscle relationship with the first anatomy train. The measurement result acquisition unit 11 is a specific example of the measurement result acquisition section.

The first anatomy train and the second anatomy train are specific examples of the anatomy train. Here, the anatomy train refers to a part that is affected by a load when a load is applied to a certain part. Examples of the anatomy trains include the following.

Superficial Front Line (SFL, simply referred to as SFL): The SFL is a fascia line that extends from the vertex of the head to the toes along the front surface, and has a role of maintaining the posture and bending the body forward. Examples of the muscle sites belonging to the SFL include the short extensor muscle of toes, the long extensor muscle of toes, the tibialis anterior muscle, the extensor hallucis longus muscle, the rectus femoris muscle, the vastus medialis muscle, the vastus lateralis muscle, the vastus intermedius muscle, the rectus abdominis muscle, the sternalis muscle, and the sternocleidomastoid muscle.

Superficial Back Line (SBL, simply referred to as SBL): The SBL is a fascia line that extends from the toes to the vertex of the head along the back surface, and has a role of maintaining the posture and bending the body backward. Examples of the muscle site belonging to the SBL include the flexor digitorum brevis muscle, the gastrocnemius muscle, the biceps femoris muscle, the semitendinosus muscle, the semimembranosus muscle, the iliocostalis muscle, the longissimus muscle, and the spinalis muscle.

Front Functional Line (FFL, simply referred to as FFL): The FFL is a fascia line that diagonally runs on the front surface of the body, connects the shoulder and the leg on the opposite side, and contributes to movement and rotation movement on a diagonal line. Examples of muscle sites belonging to the FFL include the pectoralis major muscle, the rectus abdominis muscle, and the adductor longus muscle.

Back Functional Line (BFL, simply referred to as BFL): The BFL is a fascia line that diagonally runs on the back surface of the body, connects the shoulder and the leg on the opposite side, and contributes to movement and rotation movement on a diagonal line. Examples of the muscle site belonging to the BFL include the latissimus dorsi muscle, the gluteus maximus muscle, and the vastus lateralis muscle.

The SFL and the SBL are in an antagonistic muscle relationship with each other. Similarly, the FFL and the BFL are in an antagonistic muscle relationship with each other. Therefore, when the first anatomy train is the SFL, the second anatomy train is the SBL, and when the first anatomy train is the FFL, the second anatomy train is the BFL.

Hereinafter, for convenience of description, the first anatomy train is an SFL, and the second anatomy train is an SBL, and the measurement result acquisition unit 11 will be described.

The first measurement result is a measurement result of the muscle strength measurement using the muscle sites belonging to the SFL, which is typically a measurement result of the lower limb extension muscle strength. The lower limb extension force is typically the joint torque at the knee joint when the lower limb is extended (hereinafter, referred to as the knee joint extension torque). The second measurement result is a measurement result of the muscle strength measurement using the muscle sites belonging to the SBL, which is typically a measurement result of the lower limb flexion force. The lower limb flexion force is typically the joint torque at the knee joint when the lower limb is flexed (hereinafter, referred to as a knee joint flexion torque).

The measurement result acquisition unit 11 typically acquires the first measurement result (knee joint extension torque) and the second measurement result (knee joint flexion torque) via the input interface 6.

The adjustment unit 12 executes an adjustment process of adjusting at least one of the muscle strengths of the muscle sites belonging to the SFL and the muscle sites belonging to the SBL in the musculoskeletal model selected by the musculoskeletal model selection unit 10, based on the comparison result of the knee joint extension torque and the knee joint flexion torque. Specifically, the adjustment unit 12 executes the adjustment process based on the ratio of the knee joint extension torque to the knee joint flexion torque. More specifically, the adjustment unit 12 executes the adjustment process such that the ratio of the muscle strength of the muscle sites belonging to the SFL and the muscle strength of the muscle sites belonging to the SBL in the musculoskeletal model selected by the musculoskeletal model selection unit 10 approaches the ratio of the knee joint extension torque and knee joint flexion torque of the subject. Specifically, the method is as follows.

That is, it is known that the ratio of the knee joint extension torque to the knee joint flexion torque is generally 3:2. Hereinafter, the ratio is also referred to as a reference ratio. Therefore, in any of the musculoskeletal model stored in the musculoskeletal model database 15, the ratio of the initial value of the muscle strength of the muscle sites belonging to the SFL to the initial value of the muscle strength of the muscle sites belonging to the SBL is set to 3:2.

On the other hand, as an example, the ratio in the subject is assumed to be 3.2:2. In this case, the adjustment unit 12 adjusts at least one of the muscle strength of the muscle sites belonging to the SFL and the muscle strength of the muscle sites belonging to the SBL such that the ratio of the muscle strength of the muscle sites belonging to the SFL selected in the musculoskeletal model selected by the musculoskeletal model selection unit 10 and the muscle strength of the muscle sites belonging to the SBL approaches 3.2:2. Specifically, the adjustment unit 12 adjusts at least one of the muscle strength of the muscle sites belonging to the SFL and the muscle strength of the muscle sites belonging to the SBL such that the ratio of the muscle strength of the muscle sites belonging to the SFL selected in the musculoskeletal model selected by the musculoskeletal model selection unit 10 and the muscle strength of the muscle sites belonging to the SBL is 3.2:2.

In the adjustment process described above, when solely the muscle strength of the muscle sites belonging to the SFL in the musculoskeletal model is adjusted, the adjustment unit 12 typically uniformly multiplies the initial value of the muscle strength of the muscle sites belonging to the SFL in the musculoskeletal model by 3.2/3.0=1.0667. That is, the initial values of the muscle strengths of the short extensor muscle of toes, the long extensor muscle of toes, the tibialis anterior muscle, the extensor hallucis longus muscle, the rectus femoris muscle, the vastus medialis muscle, the vastus lateralis muscle, the vastus intermedius muscle, the rectus abdominis muscle, the sternalis muscle, and the sternocleidomastoideole in the musculoskeletal model are uniformly multiplied by 3.2/3.0=1.0667. As a result, the ratio of the muscle strength of the muscle sites belonging to the SFL and the muscle strength of the muscle sites belonging to the SBL in the muscle-skeletal model selected by the musculoskeletal model selection unit 10 is 3.2:2, and substantially matches the measured ratio specific to the subject.

Similarly, in a case where solely the muscle strength of the muscle sites belonging to the SBL in the musculoskeletal model is adjusted in the adjustment process, the adjustment unit 12 typically uniformly multiplies the initial value of the muscle strength of the muscle sites belonging to the SBL in the musculoskeletal model by 3.0/3.2=0.9375. That is, the initial values of the muscle strength of the flexor digitorum brevis muscle, the gastrocnemius muscle, the biceps femoris muscle, the semitendinosus muscle, the semimembranosus muscle, the iliocostalis muscle, the longissimus muscle, and the spinalis muscle in the musculoskeletal model are uniformly multiplied by 3.0/3.2=0.9375. As a result, the ratio of the muscle strength of the muscle sites belonging to the SFL and the muscle strength of the muscle sites belonging to the SBL in the muscle-skeletal model selected by the musculoskeletal model selection unit 10 is 3.2:2, and the ratio substantially matches the ratio specific to the subject.

The inverse dynamics analysis unit 13 executes a predetermined motion on the musculoskeletal model in which the muscle strength of each muscle site is adjusted by the adjustment unit 12, and calculates the joint torque generated at each joint of the musculoskeletal model by using the inverse dynamics analysis. The predetermined motion is, for example, a sitting motion or a walking motion of the subject, or another daily motion, and is typically recorded by attaching a plurality of sensors to the subject. As a result, the inverse dynamics analysis unit 13 estimates the fatigue of the muscle site of the subject or estimates the energy consumption of the subject. The inverse dynamic analysis by the inverse dynamics analysis unit 13 is typically performed using “AnyBody” (registered trademark). The “AnyBody” is a musculoskeletal mechanics analysis software developed at Aalborg University in Denmark and widely used worldwide, and calculates a force (muscle activity amount, muscle strength and antagonistic muscle strength, elastic energy of a tendon, joint force and joint moment, and the like) acting on each part of a human body (inverse dynamics analysis) when a motion is given to a human musculoskeletal model. However, the present disclosure is not limited to this, and the inverse dynamics analysis by the inverse dynamics analysis unit 13 may be performed using other commercially available software.

The output unit 14 typically outputs and displays the analysis result by the inverse dynamics analysis unit 13 on the LCD 5.

The first embodiment has been described above. The first embodiment has the following features.

A simulation device 1 (simulation system) of a musculoskeletal model including a plurality of muscle sites disposed along a skeleton includes a measurement result acquisition unit 11 (measurement result acquisition section) configured to acquire a first measurement result that is a measurement result of muscle strength measurement using a plurality of muscle sites belonging to the SFL (the first anatomy train) of a subject and a second measurement result that is a measurement result of muscle strength measurement using a plurality of muscle sites belonging to the SBL (the second anatomy train) of the subject as a measurement result, and an adjustment unit 12 (adjustment section) configured to execute an adjustment process of adjusting at least muscle strength (muscle site parameter) of any one of the muscle sites belonging to the SFL and the muscle sites belonging to the SBL in the musculoskeletal model based on a comparison result of the first measurement result and the second measurement result. With the above configuration, it is possible to efficiently improve the accuracy of the simulation of the musculoskeletal model based on the variation in the way muscles are put on by a person.

The adjustment unit 12 executes the adjustment process based on the ratio of the first measurement result to the second measurement result. With the above configuration, the musculoskeletal model can be customized according to the ratio of the first measurement result to the second measurement result.

The adjustment unit 12 executes the adjustment process such that the ratio of the muscle strength of the muscle sites belonging to the SFL and the muscle strength of the muscle sites belonging to the SBL in the musculoskeletal model approaches the ratio of the first measurement result and the second measurement result of the subject. With the above configuration, the parameter adjustment is performed by paying attention to the divergence between the measured ratio of the subject and the ratio of the model for each of the anatomy lines.

### Second Embodiment

Next, a second embodiment of the present disclosure will be described. Hereinafter, the present embodiment will be described focusing on the differences from the first embodiment described above, and the same description will be omitted.

In the first embodiment, the adjustment unit 12 adjusts at least one of the muscle strength of the plurality of muscle sites belonging to the SFL and the muscle strength of the plurality of muscle sites belonging to the SBL in the muscle-skeletal model selected by the musculoskeletal model selection unit 10 such that the ratio of the muscle strength of the muscle sites belonging to the SFL and the muscle strength of the muscle sites belonging to the SBL in the muscle-skeletal model selected by the musculoskeletal model selection unit 10 matches the measured ratio of the subject.

On the other hand, in the adjustment process in the present embodiment, the determination is made as to which side the measured ratio of the subject deviates from the standard ratio, and the predetermined magnification is multiplied by the muscle strength of the muscle sites belonging to the deviation side anatomy train. For example, in a case where the measured ratio of the subject is 3.2:2, the measured ratio of the subject is said to deviate from the standard ratio to the extension side, and the adjustment unit 12 executes the adjustment process of multiplying the muscle strength of the muscle sites belonging to the SFL in the musculoskeletal model by a predetermined magnification.

Specifically, the adjustment unit 12 determines that the measured ratio of the subject deviates to the extension side from the standard ratio when the variable R obtained by the following equation is positive, and determines that the measured ratio of the subject deviates to the flexion side from the standard ratio when the variable R is negative. In the following equation, T means a knee joint torque, ext means extension, flx means flexion, measured means a measured value, and standard means a model reference value (model initial value). Therefore, for example, Text.measured means the measured value of the knee joint extension torque, and Tflx.standard means the model reference value (model initial value) of the knee joint flexion torque.

$$R = \frac{Text \cdot measured - Text \cdot standard}{Text \cdot standard} - \frac{Tflx \cdot measured - Tflx \cdot standard}{Tflx \cdot standard}$$

The adjustment unit 12 uniformly increases the muscle strength of the muscle sites belonging to the SFL in the musculoskeletal model by 1.2 times in a case where the variable R is positive, that is, the measured ratio of the subject deviates from the standard ratio to the extension side. Similarly, the adjustment unit 12 uniformly multiplies the muscle strength of the muscle sites belonging to the SBL in the musculoskeletal model by 1.2 when the variable R is negative, that is, when the measured ratio of the subject deviates from the standard ratio toward the flexion side. In this way, the muscle strength of the plurality of muscle sites belonging to the SFL or the SBL is uniformly multiplied by a predetermined value according to the positive or negative of the variable R, so that the adjustment process by the adjustment unit 12 is simplified.

Although the disclosure made by the present inventor has been specifically described based on the embodiments, the disclosure is not limited to the above-described embodiments, and it is needless to say that various changes can be made within the scope of the spirit of the disclosure.

For example, in the first embodiment and the second embodiment, the same magnification is applied to the muscle strength of the muscle sites belonging to the specific anatomy train of the musculoskeletal model. However, instead of this, the magnification applied to the muscle strength may be made different for each of the muscle sites according to the degree of contribution to the exercise for each of the muscle sites at the time of muscle strength measurement.

In the first embodiment and the second embodiment, the muscle strength measurement may be individually performed on the right half and the left half of the body of the subject, and the adjustment unit 12 may individually execute the adjustment process on the right half and the left half of the musculoskeletal model.

In addition, in the first embodiment and the second embodiment, the first anatomy train and the second anatomy train have been described as the SFL and the SBL. As described above, the first anatomy train and the second anatomy train may be the FFL and the BFL. In this case, the first measurement result is typically a measurement result of the shoulder joint medial rotation force, which is a measurement result of the muscle strength measurement using the muscle sites belonging to the first anatomy train. The shoulder joint internal rotation force is typically the joint torque at the shoulder joint when the shoulder joint is internally rotated. The second measurement result is a measurement result of the muscle strength measurement using a plurality of muscle sites belonging to the second anatomy train, typically, a measurement result of the shoulder joint external rotation force. The shoulder joint external rotation force is typically the joint torque at the shoulder joint when the shoulder joint is externally rotated.

What is claimed is:

1. A simulation system of a musculoskeletal model including a plurality of muscle sites disposed along a skeleton, the simulation system comprising:
a measurement result acquisition section configured to acquire a first measurement result that is a measurement result of a muscle strength measurement using a plurality of muscle sites belonging to a first anatomy train of a subject, and a second measurement result that is a measurement result of a muscle strength measurement using a plurality of muscle sites belonging to a second anatomy train of the subject, the second anatomy train having an antagonistic muscle relationship with the first anatomy train; and
an adjustment section configured to execute an adjustment process of adjusting muscle site parameters of at least one of the muscle sites belonging to the first anatomy train and the muscle sites belonging to the second anatomy train in the musculoskeletal model, based on a comparison result of the first measurement result and the second measurement result.

2. The simulation system according to claim 1, wherein the adjustment section is configured to execute the adjustment process based on a ratio of the first measurement result to the second measurement result.

3. The simulation system according to claim 2, wherein the adjustment section is configured to execute the adjustment process such that a ratio of the muscle site parameters of the muscle sites belonging to the first anatomy train to the muscle site parameters of the muscle sites belonging to the second anatomy train in the musculoskeletal model approaches the ratio of the first measurement result to the second measurement result of the subject.

4. The simulation system according to claim 1, wherein the first anatomy train is a superficial front line (SFL), and the second anatomy train is a superficial back line (SBL).

5. The simulation system according to claim 1, wherein the first anatomy train is a front functional line (FFL), and the second anatomy train is a back functional line (BFL).
